(19) United States
(12) Patent Application Publication
(10) Pub. No.: US 2012/0329234 A1
(43) Pub. Date: Dec. 27, 2012

(54) METHOD FOR FORMING A SEMICONDUCTOR DEVICE HAVING A COBALT SILICIDE

(76) Inventors: Jason T. Porter, Austin, TX (US); Dmitri Kulik, Cedar Park, TX (US)

(21) Appl. No.: 13/166,561

(22) Filed: Jun. 22, 2011

(51) Int. Cl. H01L 21/336

(52) U.S. Cl. 438/303; 257/E21.409

(57) ABSTRACT

A method includes forming a gate over a substrate having a semiconductor layer comprising silicon. The gate has a sidewall spacer on sides of the gate. The gate has a gate length less than or equal to 50 nanometers. The gate is formed of polysilicon. A cobalt layer is formed on a top of the gate and the sidewall spacer. A titanium nitride layer is formed on the cobalt layer. The titanium nitride layer has a thickness over the gate in a range of 10 to 14 nanometers. An anneal is performed to form a cobalt silicide layer on the top of the gate and leave cobalt on the sidewall spacer. An etchant is applied that etches cobalt and titanium nitride selective to cobalt silicide to the titanium nitride layer. The cobalt is on the sidewall spacer and the cobalt silicide layer. An anneal is performed to increase conductivity of the cobalt silicide layer.

### BACKGROUND

1. Field

This disclosure relates generally to semiconductor processing, and more specifically, to forming a semiconductor device having a cobalt silicide.

2. Related Art

In semiconductor processing, a self-aligned silicide (salicide) process is commonly used to reduce contact resistivity of the polysilicon gates and source/drain regions. In technologies having gate lengths greater than 55 nm, cobalt silicides are commonly formed. In one embodiment, the salicide process includes depositing a cobalt layer over a transistor, and then depositing a titanium nitride layer over the cobalt. A first anneal is performed to form a cobalt silicide on the top of the polysilicon gate and on any exposed silicon surfaces. The titanium nitride and remaining cobalt is then removed prior to performing a second anneal.

However, as technology continues to improve, gate lengths (corresponding to the width of the polysilicon lines used as the transistor gates) continue to decrease. For example, as semiconductor processing moves into the 90 nm technology nodes, where gate lengths are typically 40 to 80 nm, silicide integrations begin to move away from cobalt silicides due to the void formation in the polysilicon which occurs during the second anneal of the cobalt silicide when gate lengths are less than 55 nm. This void formation results in significant yield loss. Current solutions address this voiding issue by not using cobalt during the salicide process for gate lengths less than 55 nm. Instead, a non-cobalt layer such as nickel or nickel platinum is used in the salicide process such that, instead of forming a cobalt layer over the transistor, a nickel or nickel platinum layer is formed over the transistor. The titanium nitride can therefore be formed over the nickel or nickel platinum. The first anneal is then performed to form a nickel silicide on the top of the polysilicon gate. The titanium nitride and remaining nickel or nickel platinum is then removed prior to performing the second anneal. However, with the nickel silicide or nickel platinum silicide, void formation does not occur during the second anneal. Therefore, by using a non-cobalt layer in the salicide process, void formation can be avoided.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-sectional view of a semiconductor device in accordance with one embodiment of the present invention.

FIG. 2 illustrates a cross-sectional view of the semiconductor device of FIG. 1 at a subsequent stage in processing, in accordance with one embodiment of the present invention.

FIG. 3 illustrates a cross-sectional view of the semiconductor device of FIG. 2 at a subsequent stage in processing, in accordance with one embodiment of the present invention.

FIG. 4 illustrates a cross-sectional view of the semiconductor device of FIG. 3 at a subsequent stage in processing, in accordance with one embodiment of the present invention.

FIG. 5 illustrates a cross-sectional view of the semiconductor device of FIG. 4 at a subsequent stage in processing, in accordance with one embodiment of the present invention.

FIG. 6 illustrates a cross-sectional view of the semiconductor device of FIG. 5 at a subsequent stage in processing, in accordance with one embodiment of the present invention.

FIG. 7 illustrates a cross-sectional view of the semiconductor device of FIG. 6 at a subsequent stage in processing, in accordance with one embodiment of the present invention.

FIG. 8 illustrates a cross-sectional view of the semiconductor device of FIG. 7 at a subsequent stage in processing, in accordance with one embodiment of the present invention.

### DETAILED DESCRIPTION

In one embodiment, a semiconductor device having a gate length of less than or equal to 50 nm is formed having a cobalt silicide layer on the top of the gate of the semiconductor device. The cobalt silicide layer on the top of the gate is formed by forming a cobalt layer over the semiconductor device, and forming a titanium nitride layer having a thickness in a range of 10 to 14 nm over the cobalt layer. An anneal is performed to form a cobalt silicide layer at the top of the gate of the semiconductor device. The titanium nitride layer and remaining portions of the cobalt layer are then removed and a subsequent anneal is performed to increase the conductivity of the cobalt silicide layer. However, voids are not formed as a result of performing this subsequent anneal, even with the formation of a cobalt silicide layer, because the titanium nitride layer has thickness in the specific range of 10 to 14 nm. That is, by controlling the thickness of the titanium nitride layer to being in the range of 10 to 14 nm, voids in the gate can be avoided even during a salicide process which forms cobalt silicide on a gate having a gate length less than or equal to 50 nm.

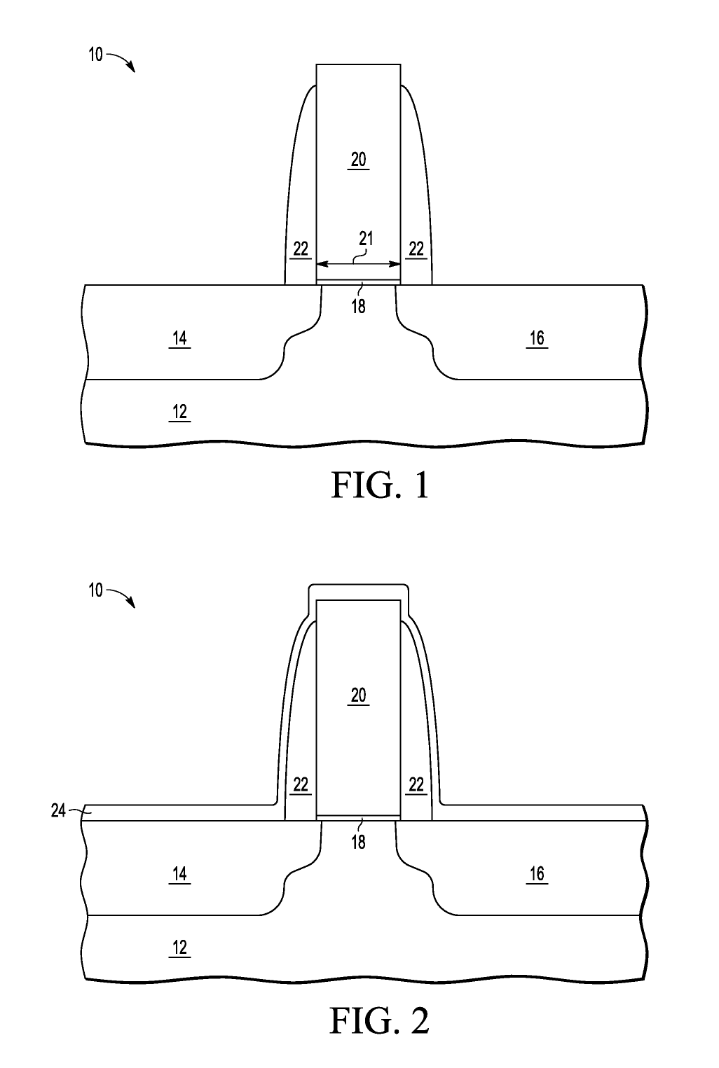

FIG. 1 illustrates a semiconductor device 10 formed in and on a semiconductor layer 12. Semiconductor device 10 may be referred to as a transistor. In the illustrated embodiment, semiconductor layer 12 is a silicon layer. However, in alternate embodiment, semiconductor layer 12 can be any semiconductor material or combinations of material such as gallium arsenide, silicon germanium, silicon-on-insulator (SOI), monocrystalline silicon, the like, and combinations of the above. Semiconductor device 10 includes a gate dielectric 18 formed on semiconductor layer 12, and a gate 20 formed on gate dielectric 18. Semiconductor device 10 includes a sidewall spacer 22 formed adjacent sidewalls of gate 20, a source/drain region 14 in semiconductor layer 12 extending laterally from a first sidewall of gate 20, and a second source/drain region 16 in semiconductor layer 12 extending laterally from a second sidewall of gate 20, opposite the first sidewall. Note that any conventional processing may be used to form gate 20, sidewall spacer 22, gate dielectric 18, and source/drain regions 14 and 16. In one embodiment, sidewall spacer 22 includes one or more dielectrics. In one embodiment, gate 20 is a polysilicon gate and has a corresponding gate length 21. Gate length 21 is less than or equal to 50 nm. Gate length 21 may also be referred to as a polysilicon line width (in which the polysilicon line width establishes the gate length of device 10). Gate 20 and gate dielectric 18 may also be referred to as a gate stack. Also, in one embodiment, one of source/drain regions 14 and 16 may be referred to as a drain region and the other of source/drain regions 14 and 16 may be referred to as a source region.

FIG. 2 illustrates semiconductor device 10 after formation of a cobalt layer 24 over semiconductor layer 12, source/drain regions 14 and 16, sidewall spacer 22, and gate 20. Cobalt layer 24 may be formed by blanket deposition, and has a thickness in a range of 6 to 10 nm. In one embodiment, prior to formation of cobalt layer, a pre-clean may be performed to remove any native oxides.

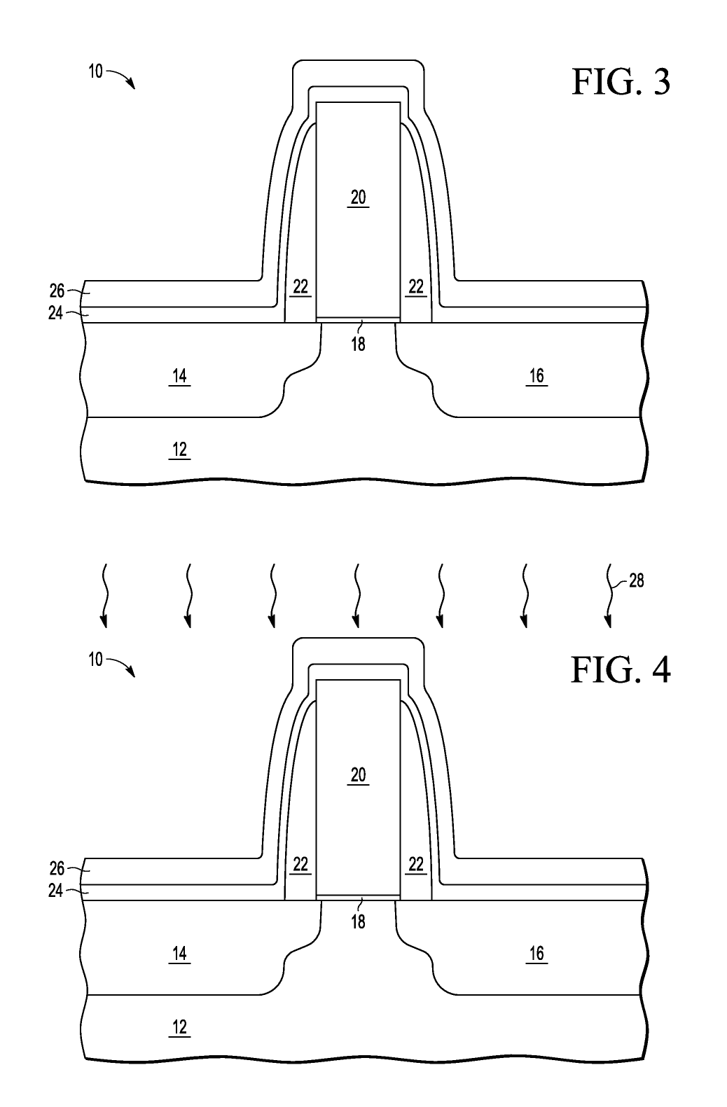

FIG. 3 illustrates semiconductor device 10 after formation of a titanium nitride layer 26 on cobalt layer 24. Titanium nitride layer 26 may be formed by blanket deposition and has a thickness in a range of 10 to 14 nm. In one embodiment, both cobalt layer 24 and titanium nitride layer 26 are formed in situ, without breaking vacuum. The thickness of each of cobalt layer 24 and titanium nitride layer 26 may be thinner along the sidewalls of sidewall spacer 22 as compared to the portions over source/drain regions 14 and 16 and on the top of gate 20. However, note that the thickness of titanium nitride layer 26 is in a range of 10 to 14 nm over the top of gate 20, even though the thickness may be less along the sidewalls of sidewall spacer 22.

FIG. 4 illustrates semiconductor device 10 while performing a first anneal 28. Anneal 28 is performed at a temperature in a range of 430 to 500 degrees Celsius.

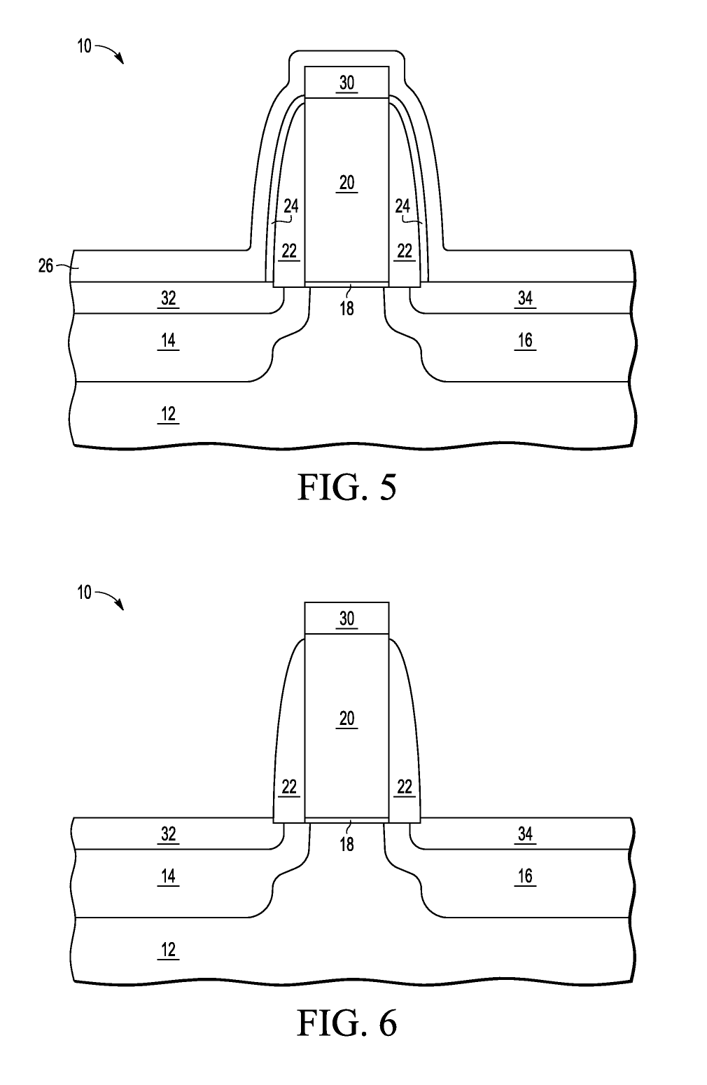

FIG. 5 illustrates semiconductor device 10 after performing anneal 28. Anneal 28 results in the formation of a cobalt silicide layer over any exposed portions of silicon, such as cobalt silicide layer 30 on the top of gate 20, cobalt silicide layer 32 on the top of source/drain region 14, and cobalt silicide layer 34 on the top of source/drain region 16. The cobalt silicide formed as a result of anneal 28 may be considered to be at a first phase or a high resistance phase of the salicide process. In one embodiment, cobalt silicide layers 30, 32, and 24 includes CoSi.

FIG. 6 illustrates semiconductor device 10 after removal of any remaining portions of cobalt layer 24 (such as the remaining portions along the sidewall of sidewall spacer 22) and the removal of titanium nitride 26. An etchant that etches cobalt and titanium nitride selective to cobalt silicide can be applied to the titanium nitride layer, the cobalt on sidewall spacer 22, and cobalt silicide layers 30, 32, and 34. In one embodiment, a same etchant may be used to remove both the remaining portions of cobalt layer 24 and titanium nitride 26. For example, the etchant may be piranha.

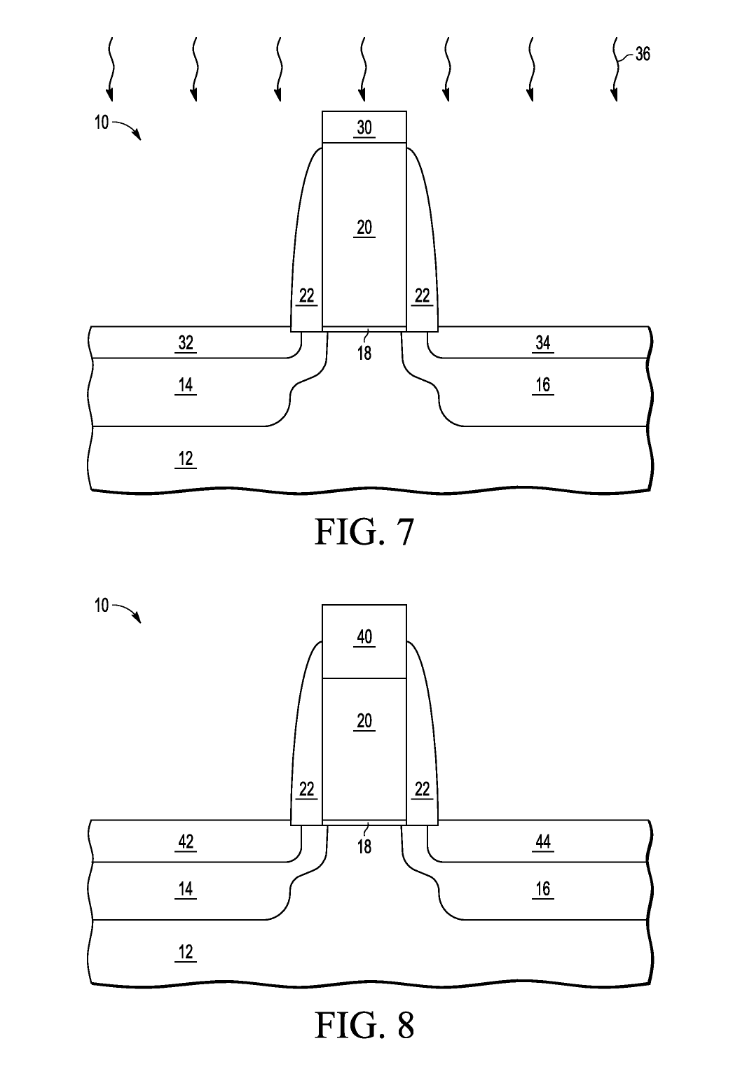

FIG. 7 illustrates semiconductor device 10 while performing a second anneal 36. Anneal 36 is performed at a temperature in a range of 700 to 800 degrees Celsius.

FIG. 8 illustrates semiconductor device 10 after performing anneal 36. Anneal 36 results in increasing the conductivity of the cobalt silicide layer. That is, anneal 36 results in the formation of cobalt silicide layer 40 on the top of gate 20, cobalt silicide layer 42 on the top of source/drain region 14, and cobalt silicide layer 44 on the top of source/drain region 16. The cobalt silicide formed as a result of anneal 36 may be considered a second phase or a low resistance phase of the salicide process. That is, anneal 36 is performed to increase the conductivity of the cobalt silicide layers. Therefore, cobalt silicide layers 40, 42, and 44 have a lower resistivity as compared to cobalt silicide layers 30, 32, and 34 formed as a result of anneal 28. In one embodiment, cobalt silicide layers 40, 42, and 44 include CoSi₂. Also, anneal 36 increases a depth of the cobalt silicide layer such that cobalt silicide layers 40, 42, and 44 have a greater depth or thickness as compared to cobalt silicide layers 30, 32, and 34.

When gate 20 has a gate length of less than or equal to 50 nm, the thickness of titanium nitride layer 26 on the top of gate 20 during anneal 28 being in the specific range of 10 to 14 nm results in reduced void formation in gate 20 during anneal 36. In this manner, yield may be improved. Thus, the process described with respect to FIGS. 1-8 may be used to form a cobalt silicide layer (such as cobalt silicide layer 40) on a top of a polysilicon line having a line width of less than or equal to 50 nm. This polysilicon line may correspond to a gate of a semiconductor device, such as gate 20. In this manner, as polysilicon line widths (e.g. gate lengths) continue to decrease to 50 nm or below, cobalt silicide may still be effectively formed on a polysilicon line without void formation in the polysilicon line if the thickness of the titanium nitride layer over the cobalt layer on the top of the gate is in the range of 10 to 14 nm.

Although the invention has been described with respect to specific conductivity types or polarity of potentials, skilled artisans appreciated that conductivity types and polarities of potentials may be reversed. For example, semiconductor device 10 may either be an N-channel or P-channel type device.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, semiconductor device 10 may be either an N-channel or P-channel type device. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

Item 1 includes a method including forming a gate over a substrate having a semiconductor layer comprising silicon, wherein the gate has a sidewall spacer on sides of the gate, the gate has a gate length less than or equal to 50 nanometers, and the gate is formed of polysilicon; forming a cobalt layer on a top of the gate and the sidewall spacer, forming a titanium nitride layer on the cobalt layer, wherein the titanium nitride layer has a thickness over the gate in a range of 10 to 14 nanometers; performing an anneal to form a cobalt silicide layer on the top of the gate and leave cobalt on the sidewall spacer; applying an etchant that etches cobalt and titanium nitride selective to cobalt silicide to the titanium nitride layer, the cobalt on the sidewall spacer, and the cobalt silicide layer; and performing an anneal to increase conductivity of the cobalt silicide layer. Item 2 includes the method of item 1, wherein a result of performing the anneal to increase conductivity does not form voids in the gate because the step of forming the titanium nitride layer formed the titanium nitride layer to be in the range of 10 to 14 nanometers. Item 3 includes the method of item 1 and further includes forming, in the semiconductor layer, a source region on a first side of the gate and a drain region on a second side of the gate prior to forming the cobalt layer. Item 4 includes the method of item 3, wherein the step of forming the cobalt layer is further characterized as being on the source region and the drain region. Item 5 includes the method of item 4, wherein the step of forming the titanium nitride layer includes forming the titanium nitride layer over the cobalt layer over the source region and the drain region. Item 6 includes the method of item 5, wherein performing the anneal to form the cobalt silicide layer forms cobalt silicide on the source region and the drain region. Item 7 includes the method of item 1, wherein the step of performing an anneal to form the cobalt silicide layer is further characterized as being performed at a temperature between 430 and 500 degrees Celsius. Item 8 includes the method of item 1, wherein the step of performing an anneal to increase the conductivity is further characterized as being performed at a temperature between 700 and 800 degrees Celsius. Item 9 includes the method of item 1, wherein the step of applying an etchant is further characterized by the etchant being piranha. Item 10 includes the method of item 1, wherein the steps of forming the cobalt layer and forming the titanium nitride layer are performed in situ.

Item 11 includes a method of forming a cobalt silicide layer on a top of a polysilicon line having a line width of less than or equal to 50 nanometers. The method includes forming a sidewall spacer on sides of the polysilicon line; forming a cobalt layer on the sidewall spacer and the top of the polysilicon line; forming a titanium nitride layer, having a thickness between 10 and 14 nanometers, on the cobalt layer; annealing to form a cobalt silicide layer on the top of the polysilicon line; removing the titanium nitride layer; removing the cobalt from the sidewall spacer; and annealing to increase a depth of the cobalt silicide layer on the top of the polysilicon line. Item 12 includes the method of item 11, wherein the annealing to form cobalt silicide is performed in a range between 430 to 500 degrees Celsius. Item 13 includes the method of item 11, wherein the step of forming the sidewall spacer is further characterized by the sidewall spacer comprising a dielectric. Item 14 includes the method of item 11, wherein the annealing to increase the depth increases a conductivity of the polysilicon line. Item 15 includes the method of item 14, wherein a result of performing the anneal to increase the depth does not form voids in the polysilicon line because the step of forming the titanium nitride layer formed the titanium nitride layer to be in the range of 10 to 14 nanometers. Item 16 includes the method of item 11, and further includes forming a source on a first side of the polysilicon line and a drain on a second side of the polysilicon line.

Item 17 includes a method of forming a transistor having a gate length of less than 50 nanometers on a silicon layer, the method including forming a gate stack having a gate on a gate dielectric over the silicon layer, wherein the gate comprises polysilicon having a width that is used to establish a gate length of the transistor at less than 50 nanometers; forming a sidewall spacer of a dielectric material on sides of the gate; forming, in the silicon layer, a source region on one side of the gate and a drain region on a second side of the gate; forming a cobalt layer on the sidewall spacer, a top of the gate, the source region, and the drain region; forming a titanium nitride layer on the cobalt layer having a thickness over the source region and the drain region between 10 and 14 nanometers; applying heat to cause formation of a drain cobalt silicide layer on the drain region, a source cobalt silicide layer on the source region, and a gate cobalt silicide region on the top of the gate; removing the titanium nitride layer and the cobalt layer on the sidewall spacer; and applying heat to increase a depth of the drain cobalt silicide layer, the source cobalt silicide layer, and the gate cobalt silicide layer. Item 18 includes the method of item 17, wherein the step of applying heat to increase the depth comprises an anneal performed at a temperature between 700 and 800 degrees Celsius. Item 19 includes the method of item 17, wherein the step forming the cobalt layer is further characterized as forming the cobalt layer to have a thickness in a range of 6 to 10 nanometers over the top of the gate, the source region, and the drain region. Item 20 includes the method of item 17, wherein a result of applying heat to increase the depth does not form voids in the gate because the step of forming the titanium nitride layer formed the titanium nitride layer to be in the range of 10 to 14 nanometers.

What is claimed is:

1. A method, comprising:
forming a gate over a substrate having a semiconductor layer comprising silicon, wherein the gate has a sidewall spacer on sides of the gate, the gate has a gate length less than or equal to 50 nanometers, and the gate is formed of polysilicon;
forming a cobalt layer on a top of the gate and the sidewall spacer,
forming a titanium nitride layer on the cobalt layer, wherein the titanium nitride layer has a thickness over the gate in a range of 10 to 14 nanometers;
performing an anneal to form a cobalt silicide layer on the top of the gate and leave cobalt on the sidewall spacer;
applying an etchant that etches cobalt and titanium nitride selective to cobalt silicide to the titanium nitride layer, the cobalt on the sidewall spacer, and the cobalt silicide layer; and
performing an anneal to increase conductivity of the cobalt silicide layer.

2. The method of claim 1, wherein a result of performing the anneal to increase conductivity does not form voids in the gate because the step of forming the titanium nitride layer formed the titanium nitride layer to be in the range of 10 to 14 nanometers.

3. The method of claim 1, further comprising forming, in the semiconductor layer, a source region on a first side of the gate and a drain region on a second side of the gate prior to forming the cobalt layer.

4. The method of claim 3, wherein the step of forming the cobalt layer is further characterized as being on the source region and the drain region.

5. The method of claim 4, wherein the step of forming the titanium nitride layer includes forming the titanium nitride layer over the cobalt layer over the source region and the drain region.

6. The method of claim 5, wherein performing the anneal to form the cobalt silicide layer forms cobalt silicide on the source region and the drain region.

7. The method of claim 1, wherein the step of performing an anneal to form the cobalt silicide layer is further characterized as being performed at a temperature between 430 and 500 degrees Celsius.

8. The method of claim 1, wherein the step of performing an anneal to increase the conductivity is further characterized as being performed at a temperature between 700 and 800 degrees Celsius.

9. The method of claim 1, wherein the step of applying an etchant is further characterized by the etchant being piranha.

10. The method of claim 1, wherein the steps of forming the cobalt layer and forming the titanium nitride layer are performed in situ.

11. A method of forming a cobalt silicide layer on a top of a polysilicon line having a line width of less than or equal to 50 nanometers, comprising:
forming a sidewall spacer on sides of the polysilicon line;
forming a cobalt layer on the sidewall spacer and the top of the polysilicon line;
forming a titanium nitride layer, having a thickness between 10 and 14 nanometers, on the cobalt layer;
annealing to form a cobalt silicide layer on the top of the polysilicon line;
removing the titanium nitride layer;
removing the cobalt from the sidewall spacer; and
annealing to increase a depth of the cobalt silicide layer on the top of the polysilicon line.

12. The method of claim 11, wherein the annealing to form cobalt silicide is performed in a range between 430 to 500 degrees Celsius.

13. The method of claim 11, wherein the step of forming the sidewall spacer is further characterized by the sidewall spacer comprising a dielectric.

14. The method of claim 11, wherein the annealing to increase the depth increases a conductivity of the polysilicon line.

15. The method of claim 14, wherein a result of performing the anneal to increase the depth does not form voids in the polysilicon line because the step of forming the titanium nitride layer formed the titanium nitride layer to be in the range of 10 to 14 nanometers.

16. The method of claim 11, further comprising forming a source on a first side of the polysilicon line and a drain on a second side of the polysilicon line.

17. A method of forming a transistor having a gate length of less than 50 nanometers on a silicon layer, comprising:
forming a gate stack having a gate on a gate dielectric over the silicon layer, wherein the gate comprises polysilicon having a width that is used to establish a gate length of the transistor at less than 50 nanometers;
forming a sidewall spacer of a dielectric material on sides of the gate;
forming, in the silicon layer, a source region on one side of the gate and a drain region on a second side of the gate;
forming a cobalt layer on the sidewall spacer, a top of the gate, the source region, and the drain region;
forming a titanium nitride layer on the cobalt layer having a thickness over the source region and the drain region between 10 and 14 nanometers;
applying heat to cause formation of a drain cobalt silicide layer on the drain region, a source cobalt silicide layer on the source region, and a gate cobalt silicide region on the top of the gate;
removing the titanium nitride layer and the cobalt layer on the sidewall spacer; and
applying heat to increase a depth of the drain cobalt silicide layer, the source cobalt silicide layer, and the gate cobalt silicide layer.

18. The method of claim 17, wherein the step of applying heat to increase the depth comprises an anneal performed at a temperature between 700 and 800 degrees Celsius.

19. The method of claim 17, wherein the step forming the cobalt layer is further characterized as forming the cobalt layer to have a thickness in a range of 6 to 10 nanometers over the top of the gate, the source region, and the drain region.

20. The method of claim 17, wherein a result of applying heat to increase the depth does not form voids in the gate because the step of forming the titanium nitride layer formed the titanium nitride layer to be in the range of 10 to 14 nanometers.
